(19) United States
(12) Patent Application Publication
(10) Pub. No.: US 2008/0018410 A1
(43) Pub. Date: Jan. 24, 2008

(54) VOLTAGE CONTROLLED OSCILLATOR

(75) Inventor: Kazuo Kawai, Tokyo (JP)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(73) Assignee: GENERAL RESEARCH OF ELECTRONICS, INC., Tokyo (JP)

(21) Appl. No.: 11/778,899

(22) Filed: Jul. 17, 2007

(30) Foreign Application Priority Data
Jul. 24, 2006 (JP) 2006-200745

(51) Int. Cl. H03L 7/00

(52) U.S. Cl. 331/1 A

(57) ABSTRACT

The present invention provides a voltage controlled oscillator capable of obtaining an oscillation signal having a relatively low frequency with a simple circuit configuration without using AGC means and a semiconductor internal resistor. The voltage controlled oscillator includes a switching circuit which inputs therein a frequency control voltage and its inverse frequency control voltage and selects and outputs the frequency control voltage or the inverse frequency control voltage in response to an output logic state of a switching voltage generating section, and an integration circuit which integrates the output voltage of the switching circuit to form a triangular wave signal. The switching voltage generating section comprises a reference window voltage generating circuit which generates two high-level and low-level window voltages, a window comparison circuit which is supplied with the two high-level and low-level window voltages and the triangular wave signal and which outputs a first voltage when the level of the triangular wave signal lies between the two high-level and low-level window voltages and outputs a second voltage when other than the above, and a logic circuit which causes the output logic state to remain unchanged upon the output of the first voltage and varies the output logic state upon the output of the second voltage, whereby a triangular wave signal having an oscillation frequency proportional to the frequency control voltage is outputted from the integration circuit.

### RELATED/PRIORITY APPLICATION

This application claims priority with respect to Japanese Application No. 2006-200745 filed Jul. 24, 2006.

### BACKGROUND OF THE INVENTION

1. Field of the Invention

The present invention relates to a voltage controlled oscillator whose oscillation frequency is controlled by an input frequency control voltage, and particularly to a voltage controlled oscillator of which an oscillation frequency lies within a relatively low frequency band and which is suitable for oscillation of an oscillation signal represented in the form of a triangular-wave waveform.

2. Description of the Related Art

In general, a voltage controlled oscillator has been used for a source oscillator of a multi-channel transmitter, a first local oscillator of each of various receivers, a clock reproduction circuit of a receiver for data transmission, and the like. The voltage controlled oscillator has been used in a frequency modulator and a frequency-modulated signal demodulator or the like as one constituent element that constitutes a phase-locked loop (PLL). Further, the voltage controlled oscillator has been used singly. In various fields, the voltage controlled oscillator has widely been used at available spots suitable for their fields.

The voltage controlled oscillator, which has been used in these fields at their available spots, almost normally outputs an oscillation signal lying in a high frequency band. When the frequency of the oscillation signal is changed, there have frequently been used ones each of which varies a capacitance value such as a junction capacitance of a variable-capacity capacitor constituting a resonant circuit or a transistor by a frequency control voltage. It is thus possible to change an oscillation frequency using a relatively simple oscillation frequency changing means.

In this type of voltage controlled oscillator, however, it is difficult to get a variable-capacity capacitor or a transistor large in variable range of its junction capacitance value where a variation range of its oscillation frequency is of a relatively low frequency band. Therefore, a circuit containing a resistor as an oscillation frequency determining element that constitutes a resonant circuit has normally been used. As the resistor configured as the oscillation frequency determining element, the internal resistance of a semiconductor element is used. Means for changing the oscillation frequency by varying the internal resistance of the semiconductor element by a frequency control voltage has been adopted.

In general, a voltage controlled oscillator that generates an oscillation signal lying in a low frequency band makes use of a circuit having carried out automatic gain control (AGC) at its amplifier circuit portion in order to stabilize the state of oscillation of the voltage controlled oscillator. The circuit configuration of the voltage controlled oscillator increases in complexity by execution of the automatic gain control. Besides, since the internal resistance of the semiconductor element used as the oscillation frequency setting element generally assumes a nonlinear change with respect to a change in frequency control voltage, it is necessary to bring the voltage controlled oscillator to such a circuit configuration as to fill the relationship between the change in the frequency control voltage and the nonlinear change in the internal resistance when the internal resistance of the semiconductor element is used. After all, the circuit configuration of the voltage controlled oscillator is apt to increase in complexity.

### SUMMARY OF THE INVENTION

The present invention has been made on the basis of such a technological background. An object of the present invention is to provide a voltage controlled oscillator capable of obtaining an oscillation signal having a relatively low frequency with a simple circuit configuration without using automatic gain control means and an internal resistance of a semiconductor element.

In order to attain the above object, there is provided a voltage controlled oscillator according to the present invention, including first constituting means which comprises a switching circuit which inputs therein a frequency control voltage and an inverse frequency control voltage obtained by polarity-inverting the frequency control voltage and selects and outputs the frequency control voltage or the inverse frequency control voltage in response to an output logic state of a switching voltage generating section, and an integration circuit which integrates the frequency control voltage or the inverse frequency control voltage outputted by the switching circuit to form a triangular wave signal, wherein the switching voltage generating section includes a reference window voltage generating circuit which generates a high-level window voltage and a low-level window voltage, a window comparison circuit which is supplied with the high-level window voltage, the low-level window voltage and the triangular wave signal and which outputs a first voltage when the level of the triangular wave signal is at a middle level between the high-level window voltage and the low-level window voltage and outputs a second voltage when the level of the triangular wave signal is at a level higher than the high-level window voltage or at a level lower than the low-level window voltage, and a logic circuit which causes the output logic state to remain unchanged when the first voltage is outputted from the window comparison circuit and varies the output logic state when the second voltage is outputted from the window comparison circuit, whereby a triangular wave signal having an oscillation frequency proportional to the frequency control voltage is outputted from the integration circuit.

In order to attain the above object, there is provided a voltage controlled oscillator including second constituting means which comprises a switching circuit which inputs therein a frequency control voltage and an inverse frequency control voltage obtained by polarity-inverting the frequency control voltage and selects and outputs the frequency control voltage or the inverse frequency control voltage in response to an output logic state of a switching voltage generating section, and an integration circuit which integrates the frequency control voltage or the inverse frequency control voltage outputted by the switching circuit to form a triangular wave signal, wherein the switching voltage generating section includes a reference voltage generating circuit which generates a reference voltage, a full-wave rectifying circuit which full-wave rectifies the triangular wave signal to generate a triangular wave signal having a frequency equal to twice that of the triangular wave signal, a comparison circuit which is supplied with the reference voltage, the double-frequency triangular wave signal and which outputs a first voltage when the level of the double-frequency triangular wave signal is less than or equal to the reference voltage and outputs a second voltage when the level of the double-frequency triangular wave signal is greater than or equal to the reference voltage, and a logic circuit which causes the output logic state to remain unchanged when the first voltage is outputted from the comparison circuit and varies the output logic state when the second voltage is outputted from the comparison circuit, whereby a triangular wave signal having an oscillation frequency proportional to the frequency control voltage is outputted from the integration circuit.

In this case, the first and second constituting means are respectively equipped with additional constituting means wherein when a fluctuation range of the frequency control voltage lies between positive and negative voltage levels with a reference level as the center, a second reference voltage is added to the frequency control voltage before the frequency control voltage is supplied directly to the switching circuit or polarity-inverted, followed by being supplied to the switching circuit, thereby to form an added frequency control voltage at which the fluctuation range thereof is always set to the positive voltage level, and the added frequency control voltage and an inverted-added frequency control voltage obtained by polarity-inverting the added frequency control voltage are supplied to the switching circuit.

The principle of operation of the voltage controlled oscillator according to the present invention will now be explained as follows using a triangular wave signal waveform diagram illustrated in FIG. 3.

When a frequency control voltage having a constant voltage value of A volts is supplied to the integration circuit as indicated by a solid line waveform shown in FIG. 3, the time T seconds required for its integrated value to reach a given voltage of B volts becomes faster as the voltage value A volts of the supplied frequency control voltage becomes larger. The time T and the voltage value A are in inverse proportional relationship. That is, assuming that the initial integrated value of the integration circuit is set to 0 volts and +B volts are reached after the elapse of the time T seconds when +A volts are supplied to the integration circuit, the polarity of the frequency control voltage is immediately inverted when the integrated value reaches +B volts, to switch the frequency control voltage from +A volts to −A volts. When such switching is done, the integrated value reaches −B volts after a time interval of 2T seconds has elapsed from +B volts. When the integrated value has reached −B volts, the polarity of the frequency control voltage is immediately inverted so that the frequency control voltage is switched from −A volts to +A volts. When such switching is done, the integrated value passes 0 volts after the time of T seconds has elapsed from −B volts and rises toward +B volts. Further, the integrated value reaches +B volts after the time of T seconds has elapsed. Thereafter, the same operation as the previous operation is repeatedly executed, so that a triangular wave signal having one cycle of 4T seconds such as indicated by the solid line waveform is obtained at the output of the integration circuit, and its oscillation frequency corresponds to ¼T Hz.

When the frequency control voltage supplied to the voltage controlled oscillator is changed from A volts used up to now to 2A volts equal to twice A volts, +2A volts or −2A volts are supplied to the integration circuit this time. Thus, since the degree (tilt) of increase in the integrated value with respect to the time becomes twice the tilt used up to now as indicated by a dotted line waveform shown in FIG. 3, one cycle or period of the triangular wave signal outputted from the integration circuit becomes 2T seconds equal to one-half the cycle set up to now, and the oscillation frequency of the triangular wave signal becomes ½T Hz equal to twice the frequency set up to now. If the magnitude of the frequency control voltage supplied to the voltage controlled oscillator is changed in this way, then oscillation signal frequency of the voltage controlled oscillator changes in proportional to the degree of change in the magnitude of the frequency control voltage.

According to the voltage controlled oscillator of the present invention as described above, advantageous effects are brought about in that since the voltage controlled oscillator is constituted of a switching circuit which switches either a frequency control voltage or an inverse frequency control voltage to be outputted in response to a binary voltage supplied from a switching voltage generating section, and an integration circuit which integrates the frequency control voltage or the inverse frequency control voltage outputted from the switching circuit, it is capable of generating an oscillation signal having a relatively low frequency with a simple circuit configuration without using automatic gain control means and the internal resistance of a semiconductor element.

Other features and advantages of the present invention will become apparent upon a reading of the attached specification.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 relates to a first embodiment of a voltage controlled oscillator according to the present invention and is a block diagram showing its fragmentary configuration;

FIG. 2 relates to a second embodiment of a voltage controlled oscillator according to the present invention and is a block diagram illustrating its fragmentary configuration; and

FIG. 3 is an oscillation output signal waveform diagram for describing the principle of operation of a voltage controlled oscillator according to the present invention.

### DETAILED DESCRIPTION OF THE PREFERRED EMBODIMENTS

Preferred embodiments of the present invention will be explained hereinafter with reference to the accompanying drawings.

### First Preferred Embodiment

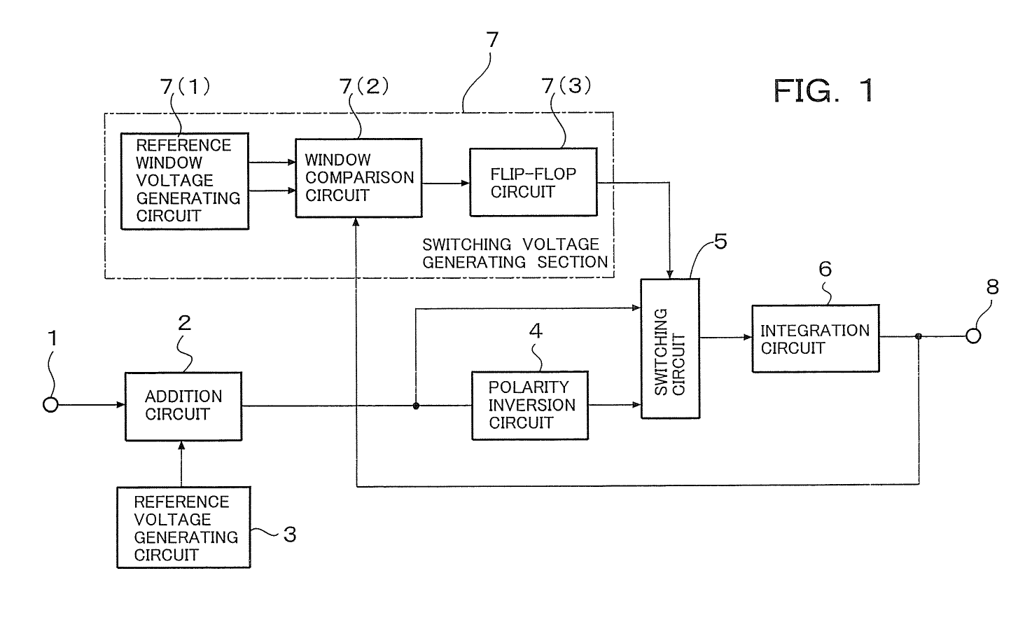

FIG. 1 relates to a first embodiment of a voltage controlled oscillator according to the present invention and is a block diagram showing a fragmentary configuration thereof.

As shown in FIG. 1, the voltage controlled oscillator according to the first embodiment comprises a frequency control voltage input terminal 1, an addition circuit 2, a reference voltage generating circuit or generator 3, a polarity inversion circuit 4, a switching circuit 5, an integration circuit 6, a switching voltage generating section 7 and an oscillation signal output terminal 8. In this case, the switching voltage generating section 7 includes a reference window voltage generating circuit 7(1), a window comparison circuit 7(2) and a flip-flop circuit 7(3).

The addition circuit 2 has a first input end connected to the frequency control voltage input terminal 1, a second input end connected to an output end of the reference voltage generating circuit 3, and an output end connected to an input end of the polarity inversion circuit 4 and a first input end of the switching circuit 5. The polarity inversion circuit 4 has an output end connected to a second input end of the switching circuit 5. The switching circuit 5 has an output end connected to an input end of the integration circuit 6, and a control end connected to an output end of the flip-flop circuit 7(3) via an output end of the switching voltage generating section 7. The integration circuit 6 has an output end connected to a third input end of the window comparison circuit 7(2) through the oscillation signal output terminal 8 and a control end of the switching voltage generating section 7. At the switching voltage generating section 7, the window comparison circuit 7(2) has a first input end connected to a high-level window voltage output end of the reference window voltage generating circuit 7(1), a second input end connected to a low-level window voltage output end of the reference window voltage generating circuit 7(1), and an output end connected to an input end of the flip-flop circuit 7(3).

The voltage controlled oscillator based on the above configuration is operated as follows:

When a frequency control voltage for setting an oscillation frequency is supplied to the frequency control voltage input terminal 1, the addition circuit 2 adds the frequency control voltage to a reference voltage supplied from the reference voltage generating circuit 3 to form an added frequency control voltage. The added frequency control voltage is supplied directly to the first input end of the switching circuit 5 and inverted in polarity by the polarity inversion circuit 4, followed by being supplied to the second input end of the switching circuit 5 as an inverted-added frequency control voltage. In this case, the reason why the reference voltage is added to the frequency control voltage is that when the fluctuation range of the frequency control voltage extends over a positive voltage and a negative voltage, the reference voltage is added to the frequency control voltage to allow the fluctuation range of the adder frequency control voltage to fall within a positive voltage range. When, for example, the frequency control voltage is of a sinusoidal voltage and frequency modulation based on the sinusoidal voltage is effected on an oscillation signal, the present reference voltage is used to determine a center frequency at the frequency-modulated signal. At this time, a relationship of reference voltage>sinusoidal voltage is established. Assuming that the value of the reference voltage is E and the sinusoidal voltage is a sin ωt, the voltage value E is selected in such a manner that each instantaneous value of E+a sin ωt is always brought to a positive voltage.

On the other hand, when the negative voltage is not reached even when the frequency control voltage for setting the oscillation frequency is under any varying state, the addition circuit 2 and the reference voltage generating circuit 3 are unnecessary, and the frequency control voltage is directly supplied to the first input end of the switching circuit 5 and the input end of the polarity inversion circuit 4, respectively.

The switching circuit 5 is changed over depending on an output logic state of the switching voltage generating section 7. When the switching voltage generating section 7 is brought to one output logic state, a state in which the frequency control voltage supplied to the first input end is supplied to the following integration circuit 6 or a state in which the inverse frequency control voltage supplied to the second input end is supplied to the following integration circuit 6 is maintained as it is. When, however, the switching voltage generating section 7 is brought to another output logic state, the switching circuit 5 changes the state in which the frequency control voltage supplied to the first input end is supplied to the integration circuit 6 to the state in which the inverse frequency control voltage supplied to the second input end is supplied to the integration circuit 6 or changes the latter state to the former state.

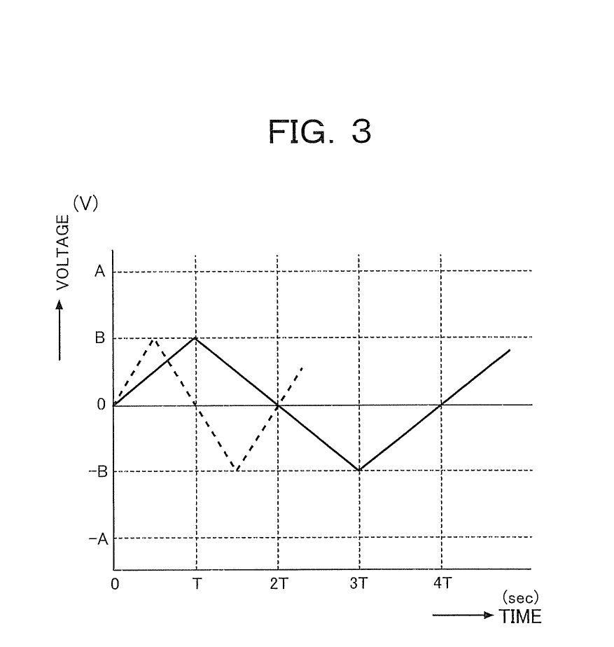

At this time, as shown in FIG. 3, the integration circuit 6 repeatedly executes such an operation that when a frequency control voltage of A volts is supplied, the integration circuit 6 integrates the frequency control voltage and sequentially increases its integrated value linearly, that when the integrated value reaches +B volts, the value of a binary voltage is switched so that an inverse frequency control voltage of −A volts is supplied to the integration circuit 6, after which it integrates the inverse frequency control voltage and sequentially decreases its integrated value linearly, and that when the integrated value reaches −B volts, the value of the binary voltage is switched again so that a frequency control voltage of +A volts is supplied to the integration circuit 6, after which it integrates the frequency control voltage and sequentially increases its integrated value linearly. As a result, a triangular wave signal that travels between +B volts and −B volts is outputted from the integration circuit 6 and supplied to the oscillation signal output terminal 8.

Means for varying the output logic state of the switching voltage generating section 7 thereat will next be explained.

The reference voltage generating circuit 7(1) generates a high-level window voltage of +B volts and a low-level window voltage of −B volts respectively and supplies the same to the window comparison circuit 7(2). The window comparison circuit 7(2) is supplied with the high-level window voltage of +B volts, the low-level window voltage of −B volts and the triangular wave signal supplied to the oscillation signal output terminal 8 and compares the level of the triangular wave signal, the high-level window voltage of +B volts and the low-level window voltage of −B volts. When it is found by the level comparison that the level of the triangular wave signal exists between the high-level window voltage of +B volts and the low-level window voltage of −B volts, the window comparison circuit 7(2) outputs a low-level voltage value. On the other hand, when the level of the triangular wave signal is higher than the high-level window voltage of +B volts or lower than the low-level window voltage of −B volts, the window comparison circuit 7(2) outputs a high-level voltage value. Since the output logic state of the flip-flop circuit 7(3) remains unchanged during a period in which the low-level voltage value is being supplied from the window comparison circuit 7(2), the output to be selected by the switching circuit 5 is not switched. On the other hand, when the high-level voltage is supplied from the window comparison circuit 7(2) is supplied, the output logic state of the flip-flop circuit 7(3) changes so that the output to be selected by the switching circuit 5 is switched.

When the selected output of the switching circuit 5 is switched, the polarity of the frequency control voltage (or inverse frequency control voltage) which has been supplied to the integration circuit 6 until that point in time, is inverted. Therefore, its integrated value changes in an antipolarity direction from the time of its polarity inversion. That is, the output oscillation signal is fed back to the switching voltage generating section 7, where its peak voltage is monitored. When the output oscillation signal exceeds a set high-peak voltage value or a low-peak voltage value, the polarity of the frequency control voltage (or inverse frequency control voltage) supplied to the integration circuit 6 is inverted to pull back the level of the oscillation signal from the high (low)-peak voltage value to the low (high)-peak voltage value.

If the integration circuit 6 is set to one using an op amplifier in this case, there can then be obtained one having a nearly ideal integration characteristic. If, however, the charge/discharge of an integrated value is performed using only a portion near a linear curve of an exponential function curve even in the case of a simple low-pass filter type integration circuit constituted of only a resistor and a capacitor, it is then possible to considerably reduce a signal distortion component at voltage-to-frequency conversion.

The triangular wave signal formed by the voltage controlled oscillator may be outputted as it is. If, however, a triangular wave-rectangular wave conversion circuit having a known configuration is connected between the output end of the integration circuit 6 and the oscillation signal output terminal 8 according to the usage purpose of the oscillation signal, or a waveform conversion circuit such as a triangular wave-sine wave conversion circuit is connected therebetween according to the usage purpose thereof, the waveform of the oscillation signal can be taken out as a rectangular wave signal waveform or a sinusoidal signal waveform.

Although the above description has been made of the case in which the frequency control voltage supplied to the integration circuit 6 is defined as a constant dc voltage, the frequency control voltage needs not to be defined as the constant dc voltage. Even though the frequency control voltage is of a frequency control voltage that varies in voltage value on a temporal basis, similar operations can be done. If one that varies in sinusoidal form is used as the frequency control voltage in particular, it is then possible to output a triangular wave signal frequency-modulated as an oscillation-outputted triangular wave signal.

### Second Preferred Embodiment

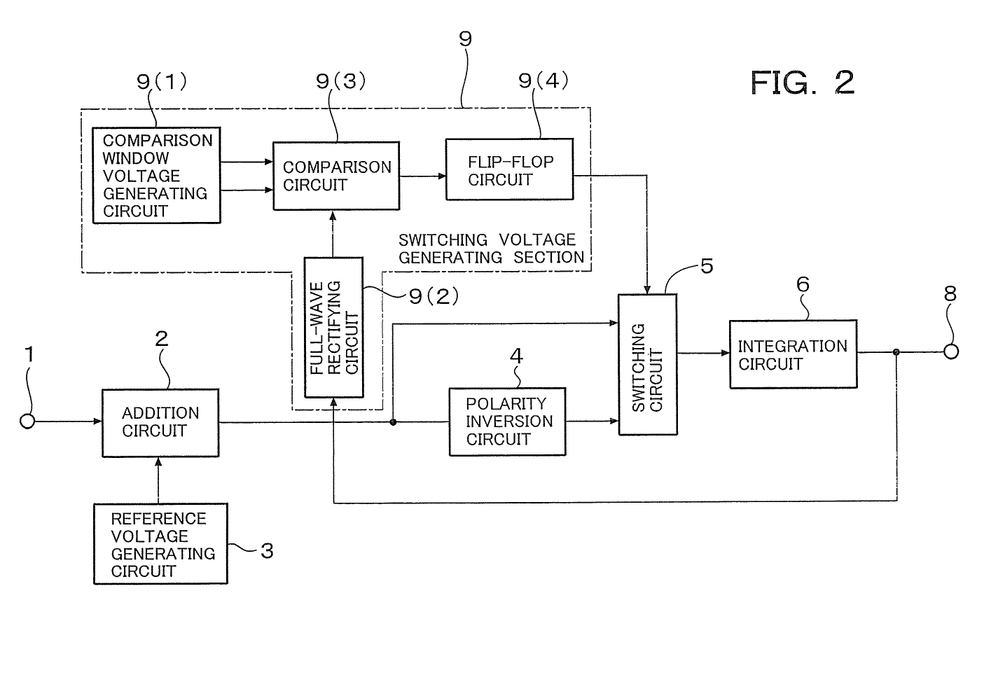

Next, FIG. 2 relates to a second embodiment of a voltage controlled oscillator according to the present invention and is a block diagram showing its fragmentary configuration.

As shown in FIG. 2, the voltage controlled oscillator according to the second embodiment is identical to the voltage controlled oscillator according to the first embodiment in that it comprises a frequency control voltage input terminal 1, an addition circuit 2, a reference voltage generating circuit 3, a polarity inversion circuit 4, a switching circuit 5, an integration circuit 6, an oscillation signal output terminal 8 and a switching voltage generating section 9. However, the switching voltage generating section 9 according to the second embodiment is different in internal configuration from that according to the first embodiment and includes a comparison voltage generating circuit 9(1), a full-wave rectifying circuit 9(2), a comparator or comparison circuit 9(3) and a flip-flop circuit 9(4). The full-wave rectifying circuit 9(2) has an input end connected to the oscillation signal output terminal 8 and an output end connected to a first input end of the comparison circuit 9(3). The comparison circuit 9(3) has a second input end connected to an output end of the comparison voltage generating circuit 9(1) and an output end connected to an input end of the flip-flop circuit 9(4). The flip-flip circuit 9(4) has an output end connected to a control end of the switching circuit 5.

Means for varying an output logic state of the switching voltage generating section 9 thereat in this case will next be explained.

The full-wave rectifying circuit 9(2) full-wave rectifies an output oscillation signal and displaces or varies a triangular wave signal varying between +B volts and −B volts between +B volts and 0 volts thereby to convert the triangular wave signal to a triangular wave signal having a double frequency, and supplies the triangular wave signal to the comparison circuit 9(3). The reference voltage generating circuit 9(1) generates a comparison voltage of +B volts and supplies it to the comparison circuit 9(3) in like manner. The comparison circuit 9(3) level-compares the triangular wave signal and the comparison voltage. When the level of the triangular signal does not reach +B volts, the comparison circuit 9(3) outputs a low-level voltage value. On the other hand, when the level of the triangular signal reaches +B volts, the comparison circuit 9(3) outputs a high-level voltage value. Since the output logic state of the flip-flop circuit 9(4) remains unchanged during a period in which the low-level voltage value is supplied from the comparison circuit 9(3), the output to be selected by the switching circuit 5 is not switched. On the other hand, when the high-level voltage value is supplied from the comparison circuit 9(3), the output logic state of the flip-flop circuit 9(4) changes so that the output to be selected by the switching circuit 5 is switched.

When the selected output of the switching circuit 5 is switched, the polarity of the frequency control voltage (or inverse frequency control voltage) which has been supplied to the integration circuit 6 until that point in time, is inverted. Therefore, its integrated value changes in an antipolarity direction from the time of its polarity inversion. That is, when the output oscillation signal is fed back to the switching voltage generating section 9, the switching voltage generating section 9 monitors its peak voltage value. When the output oscillation signal reaches a set high-peak voltage value, the polarity of the frequency control voltage (or inverse frequency control voltage) supplied to the integration circuit 6 is inverted, so that a required oscillation signal is obtained.

The switching voltage generating section 9 according to the second embodiment full-wave rectifies the triangular wave signal corresponding to the output oscillation signal by using the full-wave rectifying circuit 9(2) thereby to obtain the double-frequency triangular wave signal equal to twice the original triangular wave signal frequency. Therefore, it is enough if the reference voltage generating circuit 9(1) for generating one reference voltage and the comparison circuit 9(3) for comparing the level of the double-frequency triangular wave signal and the level of the reference voltage are used. The switching voltage generating section 9 can be simplified in configuration as compared with the switching voltage generating section 7 according to the first embodiment.

When the frequency control voltage for setting the oscillation frequency is not brought to a negative voltage even in the case of being in any varying state, the addition circuit 2 and the reference voltage generating circuit 3 are unnecessary even in the second embodiment. Further, the frequency control voltage is directly supplied to a first input end of the switching circuit 5 and an input end of the polarity inversion circuit 4 respectively.

The triangular wave signal formed by the voltage controlled oscillator according to the second embodiment may be outputted as it is. If, however, a triangular wave-rectangular wave conversion circuit having a known configuration is connected between the output end of the integration circuit 6 and the oscillation signal output terminal 8 according to the usage purpose of the oscillation signal, or a waveform conversion circuit such as a triangular wave-sine wave conversion circuit is connected therebetween according to the usage purpose thereof in a manner similar to the first embodiment, then the waveform of the oscillation signal can be taken out as a rectangular wave signal waveform or a sinusoidal signal waveform.

Further, although the second embodiment also has explained the frequency control voltage supplied to the integration circuit 6 as being the constant dc voltage, the frequency control voltage needs not to be defined as the constant dc voltage. Even though the frequency control voltage is of a frequency control voltage that varies in voltage value with time, similar operations can be done. If one that varies in sinusoidal form is used as the frequency control voltage in particular, it is then possible to output a triangular wave signal frequency-modulated as an oscillation-outputted triangular wave signal.

While the preferred forms of the present invention have been described, it is to be understood that modifications will be apparent to those skilled in the art without departing from the spirit of the invention. The scope of the invention is to be determined solely by the following claims.

What is claimed is:

1. A voltage controlled oscillator comprising:
a switching circuit which inputs therein a frequency control voltage and an inverse frequency control voltage obtained by polarity-inverting the frequency control voltage and selects and outputs the frequency control voltage or the inverse frequency control voltage in response to an output logic state of a switching voltage generating section; and
an integration circuit which integrates the frequency control voltage or the inverse frequency control voltage outputted by the switching circuit to form a triangular wave signal,
wherein the switching voltage generating section includes a reference window voltage generating circuit which generates a high-level window voltage and a low-level window voltage, a window comparison circuit which is supplied with the high-level window voltage, the low-level window voltage and the triangular wave signal and which outputs a first voltage when the level of the triangular wave signal is at a middle level between the high-level window voltage and the low-level window voltage and outputs a second voltage when the level of the triangular wave signal is at a level higher than the high-level window voltage or at a level lower than the low-level window voltage, and a logic circuit which causes the output logic state to remain unchanged when the first voltage is outputted from the window comparison circuit and varies the output logic state when the second voltage is outputted from the window comparison circuit,
whereby a triangular wave signal having an oscillation frequency proportional to the frequency control voltage is outputted from the integration circuit.

2. A voltage controlled oscillator comprising:
a switching circuit which inputs therein a frequency control voltage and an inverse frequency control voltage obtained by polarity-inverting the frequency control voltage and selects and outputs the frequency control voltage or the inverse frequency control voltage in response to an output logic state of a switching voltage generating section; and
an integration circuit which integrates the frequency control voltage or the inverse frequency control voltage outputted by the switching circuit to form a triangular wave signal,
wherein the switching voltage generating section includes a reference voltage generating circuit which generates a reference voltage, a full-wave rectifying circuit which full-wave rectifies the triangular wave signal to generate a triangular wave signal having a frequency equal to twice that of the triangular wave signal, a comparison circuit which is supplied with the reference voltage, the double-frequency triangular wave signal and which outputs a first voltage when the level of the double-frequency triangular wave signal is less than or equal to the reference voltage and outputs a second voltage when the level of the double-frequency triangular wave signal is greater than or equal to the reference voltage, and a logic circuit which causes the output logic state to remain unchanged when the first voltage is outputted from the comparison circuit and varies the output logic state when the second voltage is outputted from the comparison circuit,
whereby a triangular wave signal having an oscillation frequency proportional to the frequency control voltage is outputted from the integration circuit.

3. The voltage controlled oscillator according to either claim 1 or 2, wherein when a fluctuation range of the frequency control voltage lies between positive and negative voltage levels with a reference level as the center, a second reference voltage is added to the frequency control voltage before the frequency control voltage is supplied directly to the switching circuit or polarity-inverted, followed by being supplied to the switching circuit, thereby to form an added frequency control voltage at which the fluctuation range thereof is always set to the positive voltage level, and the added frequency control voltage and an inverted-added frequency control voltage obtained by polarity-inverting the added frequency control voltage are supplied to the switching circuit.

4. The voltage controlled oscillator according to claim 3, wherein the frequency control voltage has a fluctuation state that varies in sinusoidal form.

5. The voltage controlled oscillator according to any one of claims 1 to 4, wherein a triangular wave-sine wave converter is connected to the output side of the integration circuit, and
wherein the triangular wave-sine wave converter converts the triangular wave signal outputted from the integration circuit to a sinusoidal signal and outputs the same therefrom.
